(19) United States
(12) Patent Application Publication
(10) Pub. No.: US 2003/0105912 A1
(43) Pub. Date: Jun. 5, 2003

(54) Space efficient backup technique in a storage system

(76) Inventor: Gregory T. Noren, The Woodlands, TX (US)

Correspondence Address: CONLEY ROSE, P.C., P. O. BOX 3267, HOUSTON, TX, 77253-3267, US

(21) Appl. No.: 09/998,513

(22) Filed: Nov. 30, 2001

(51) Int. Cl. G11C 5/00

(52) U.S. Cl. 711/1

(57) ABSTRACT

Instead of storing a previous version of file, a backup technique stores a transformation operator which reflects the differences between a previous version of a file and a subsequent version. The operator may include the difference between a numerical value in the previous file version and the corresponding value in a subsequent version. Further, the transformation operator may indicate textual or binary changes between the file versions. To recover the previous version, the transformation operator is applied to the newer version to regenerate the previous version. If desired, multiple transformation operators can be maintained for a given file to be able to regenerate more than just the immediately preceding version of the file, thereby creating a multilevel backup system. The transformation operators preferably are stored in a RAID-type storage system for fault tolerance.

### CROSS-REFERENCE TO RELATED APPLICATIONS

Not applicable

### STATEMENT REGARDING FEDERALLY SPONSORED RESEARCH OR DEVELOPMENT

Not applicable.

### BACKGROUND OF THE INVENTION

1. Field of the Invention

The present invention generally relates to a data backup technique used in a computer system. More particularly, the present invention relates to backing up a file without storing the old version of the file. Still more particularly, the invention relates to backing up a file by using a RAID storage system to store information that indicates the relationship between a new version of a file and an old version of the file.

2. Background of the Invention

Virtually as long as it has been possible to store information in a computer system, it has been desirable and possible to backup such information in the event the primary source of the information becomes unusable for some reason. There are at least two reasons for wanting to retrieve an older version of a file. One reason might be that the hard drive on which the file is stored fails rendering the drive's contents inaccessible. Accordingly, if the contents of the drive had been backed up, for example, to a tape, then the defective drive could be replaced with a virgin drive and the contents of the tape written to the new drive. In this scenario, any new files created or old files edited since the last backup tape was created disadvantageously will be lost, but that is generally far better than not having a backup at all.

Another reason for needing to retrieve an older version of a file, and the reason to which the present invention has most applicability, is when a user opens an existing file and overwrites all or a portion of the existing file in an attempt to create a new file. When the user goes to save the new file to disk, the user of course should click the “save as” (or equivalent) function to be able to save the changes as a new file altogether. It is possible, however, that the user will mistakenly click the “save” function which simply causes the changes to be saved, effectively overwriting the original file. This mistake is extremely frustrating and is not uncommon, even for experienced computer users.

The problem noted above can be resolved if a backup copy of the original file is available to be retrieved. Many organizations have a backup system which is used to make a periodic backup of selected files or the entire drive. The backups are typically made once per week or even once per day. Such a system is generally effective, but is not problem free and has various limitations on its overall effectiveness. For example, the backup hardware, which generally comprises a sophisticated, high density tape drive and tape media, is expensive. Further, the backup system itself introduces a potential point of failure in that the tape drive may fail impairing the ability of the system to create backups. If the backup tape itself becomes defective such that its contents cannot be retrieved, the system is effectively left without any backup of the disk drive's data. This problem is compounded by the fact the organization must use additional tape media in order to create a complete data backup as their overall number of files grows beyond the storage capacity of the individual tape media. Also, various types of backup systems may need maintenance further adding to the complexity and expense of the organization's computer system. Such maintenance activities may include, for example, tape retensioning and tape drive cleaning, each of which is important for extending the operational effectiveness and continued error-free performance of the backup system. Another limitation of a tape-based backup system is the periodic schedule in which it is used. No matter how frequently a tape backup gets performed, one or more files may receive multiple changes or updates in between the points of time where backup copies are made, thereby missing backups of some of the actual file changes. Also, tape-based backups can take considerable time to complete, depending upon the amount of data to backup and the data transfer rates of the backup device, which, in part, may lead to restrictions on when the organization can schedule and perform their backup operations and possibly lengthen the window of time until critical file changes are safely backed up. As an alternative, full backup copies of files could be stored on the same disk drive on which the primary files are stored, but that dramatically reduces the usable storage capacity of the drive, especially as multiple, successive copies get made in order to preserve several older versions of the file in question.

For these reasons, an improved backup system is needed. Such a system should address one or more of the problems noted above. Specifically, a new backup system preferably should be fairly inexpensive, comprehensive, fast, fault tolerant, and maintenance free. Despite the obvious advantages such a backup system would provide, to date no such system is known to exist.

### BRIEF SUMMARY OF THE INVENTION

The problems noted above are solved by a backup technique in which a previous version of a file is not stored. Instead, a transformation operator is computed based on the differences between a previous version of a file and a subsequent version of the file. The transformation operator may include the difference between a numerical value in the previous file version and the corresponding value in the subsequent file version. Alternatively or additionally, the transformation operator may indicate words that have been deleted from the previous version and those words that are present in the subsequent version that are not present in the previous version. Transformation operators are calculated at the instant of time when a file gets updated, such as on a file “Save” operation, thus making the backup version of the file immediately available.

To recover the previous version, the transformation operator is applied to the newer version to recompute or regenerate the previous version. If desired, multiple transformation operators can be maintained for a given file to be able to regenerate more than just the immediately preceding version of the file, thereby creating a multi-level backup system.

Additionally, the transformation operators, which preferably are stored in a file that is separate from the file being backed up, are stored on a Redundant Array of Independent Disk (“RAID”) storage subsystem to provide fault tolerance in the backup technique. Overall, the backup capabilities of the transformation operator-based backup technique described herein is simple, quick to complete and have access to backup versions of files, covers every change made to files, requires much less storage capacity than storing previous versions of entire files, does not require additional backup equipment, and is fault tolerant. These and other advantages and benefits will become apparent upon reviewing the following disclosure.

### BRIEF DESCRIPTION OF THE DRAWINGS

For a detailed description of the preferred embodiments of the invention, reference will now be made to the accompanying drawings in which:

FIGS. 1A and 1B conceptually depict the use of a transformation operator to reflect how an old version of a file can be turned into a new version, and vice versa;

FIG. 2 illustrates the use of transformation operator to provide multiple levels of backup;

FIG. 3 illustrates an alternative use of transformation operator to provide multiple levels of backup;

FIG. 4 is a preferred computer system diagram in which a Redundant Array of Independent Disk (“RAID”) is included as the storage subsystem of the computer.

### NOTATION AND NOMENCLATURE

Certain terms are used throughout the following description and claims to refer to particular system components. As one skilled in the art will appreciate, computer companies may refer to a given component by different names. This document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect or direct electrical connection. Thus, if a first device “couples” to a second device, that connection may be through a direct electrical connection, or through an indirect electrical connection via other devices and connections. To the extent that any term is not specially defined in this specification, the intent is that the term is to be given its plain and ordinary meaning.

### DETAILED DESCRIPTION OF THE PREFERRED EMBODIMENTS

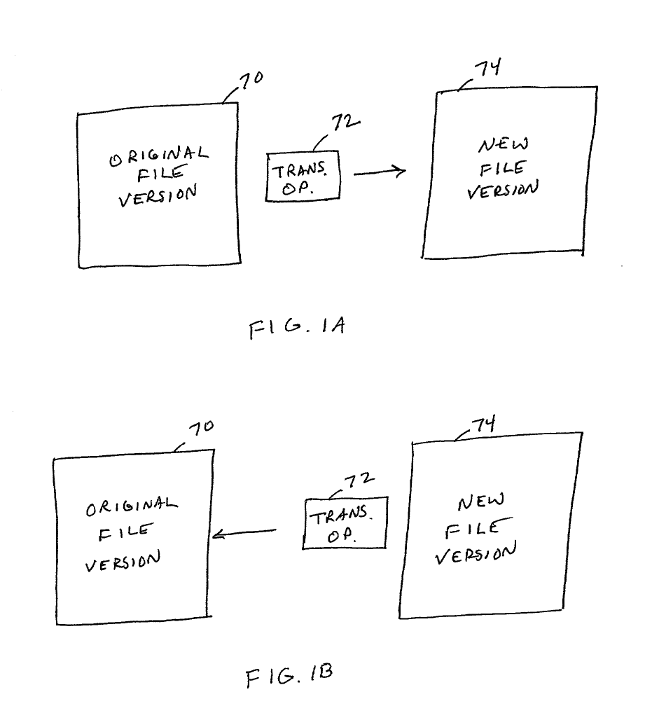

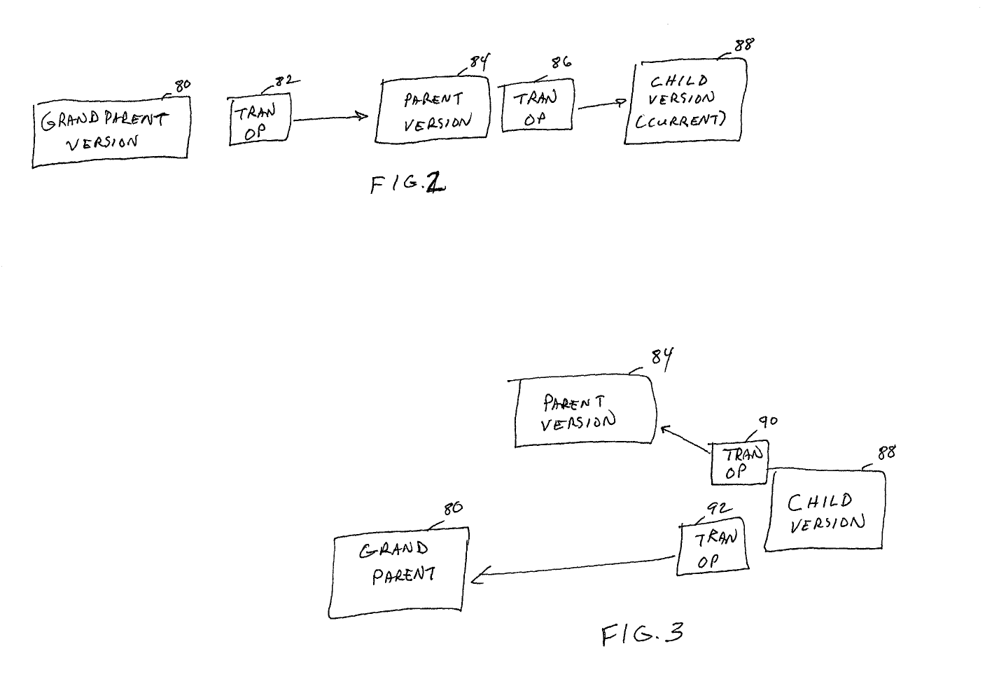

In accordance with a preferred embodiment of the invention, one or more files on a computer system are backed up without storing an entire copy of the original version of the file. Instead, the “backup” comprises information which is used to transform the original version into the new version. This process is illustrated conceptually in FIGS. 1A and 1B.

FIGS. 1A and 1B show two versions of the same file-an original version 70 and a new version 74. The difference between the two versions is that one or more pieces of information in original version 70 has been changed or deleted and/or new information is present in new version 74 that was not present in original version 70. The files 70, 74 may be, for example, text files, spreadsheets or, in general, any type of information.

The changes between original version 70 and new version 74 are stored in or otherwise represented by transformation operator 72. The representation of the changes can be in accordance with any desired format or protocol. For example, if a particular numerical value in original version 70 is changed to a new value in the new version 74, the transformation operator 72 may include the difference between the two values along with an indication of value to which such difference pertains. If the original value was 3 and the new value is 4, the difference would be a 1 and thus the transformation operator might simply include a +1 associated with the effected value to indicate that a value of +1 was added to the original value to arrive at the new value. Alternatively, the transformation operator might include a value of −1 to indicate that a value of 1 should be subtracted from the new value to regenerate the original value. Further still, rather than storing the difference between the two original and new values, the transformation operator could store the new value itself. This may be a more appropriate format for representing differences when the value is a binary encoded value, such as the contents of encrypted, audio, or video files, or possibly an alphanumeric character string, such as a text word or sentence. Additionally, differences between values, particularly text, can be represented by indicating those words, for example, that have been deleted from the original version and those words that are added to the new version, akin to the “track changes” function in Microsoft's Word application. Numerous other representations of transformation operators are envisioned and possible.

Regardless of how the changes are tracked, the transformation operator 72 provides information relevant to the differences between the original and new file versions. Information pertaining to similarities between the original and new versions may also be included as part of the transformation operator, but preferably such information is avoided or at least kept to a minimum. Because generally the transformation operator 72 includes just difference information, the transformation operator is generally smaller than either the original or new file versions 70, 74.

In accordance with the preferred embodiment of the invention, the transformation operator may be created or updated upon saving a file. As such, each time the file is “saved,” the transformation operator associated with that file is updated to reflect the changes between the file version last saved and the new version just now saved. This can be accomplished by temporarily retaining the original version and comparing the original and newly created versions to create the operator. Then, the original version can be deleted as it can now be restored at any time by application of the transformation operator to the new version of the file. Thus, all changes made to the file are preserved, that is, backed up, the moment the updated file is saved to disk. This type of system provides a single level of backup capability meaning that only the immediately preceding version of the file is recoverable, not versions older than that. It may be desirable, however, to be able to recreate a version of a file from two or more saves ago. Accordingly, as described below multiple transformation operators 72 can be maintained for each file.

Referring now to FIG. 2, three versions of the same file are shown as “grandparent” version 80, “parent” version 84, and “child” version 88. Transformation operator 82 reflects the transformation of the grandparent version 80 to the parent version 84, while transformation operator 86 reflects the transformation from parent version 84 to the child version 88. Thus, using the child version 88 and transformation operator 86, the parent version 84 can be recovered. Then, using the parent version 84 and transformation operator 82, the grandparent version 80 can be recovered. As many transformation operators can be maintained for each file as levels of recovery are desired. For example, if five levels of recovery are desired, then five transformation operators are maintained.

In FIG. 2, each transformation operator thus converts one file version to an immediately adjacent version (when viewed as a time sequence). As an alternative to what is shown in FIG. 2, each transformation operator can be computed to convert the current version of the file (version 88 in the example of FIG. 2) to a specific prior version and not simply the immediately preceding version. This technique is illustrated in FIG. 3. Transformation operator 90 permits the recreation of parent version 84 and transformation operator 92 permits the recreation of grandparent version 80. The transformation operator 92 preferably is computed using the information contained in the transformation operator 90 as would be appreciated by one of ordinary skill in the art.

FIG. 1B illustrates the process for recovering the original version 70 of the file when it has been overwritten by a new version 74. Generally, the transformation operator 72 is applied to the new version 74 to recreate the original version 70. Of course, how the transformation operator 72 is applied depends on the format of how the differences are represented in the transformation operator 72. If the differences comprise values that are the difference between old and new numerical values, then those difference values will be added to or subtracted from the changed values in the new version 74 to calculate the values in the original version 70. If the changes specify how text was changed (words added, deleted, etc.), then those changes will have to be undone (i.e., any added words will have to be deleted and any deleted words will have to be added back). The transformation operators in FIGS. 2 and 3 are also applied in a similar fashion to recover the older file versions.

An advantage of the transformation operator, versus simply backing up the entire original file version, is that sufficient information to get back the original version is present without having to store the entire original version of the file. Thus, the backup information takes up less space than would be required for the entire original version. In fact, if desired, the transformation operators 72 can be stored on the same drive as the primary file itself and the usable capacity of the drive is greater than if backup copies of the files themselves were kept on the drive.

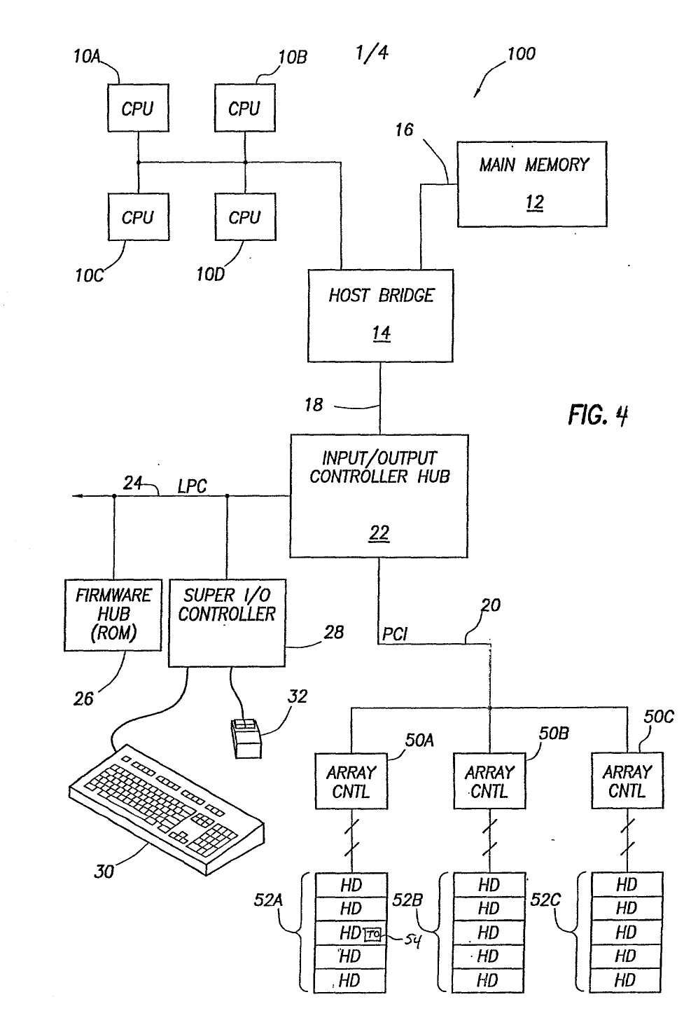

If desired, the transformation operators 72 can be stored in a manner that results in fault tolerance. Fault tolerance refers to a system that can recover from a fault or failure of an operational process or individual component of that system. One way to make the transformation operators fault tolerant is store them on a Redundant Array of Independent Disk (“RAID”) storage subsystem. An exemplary embodiment of such a system is shown in FIG. 4. It should be recognized, however, that numerous other architectures are possible as well. As will be explained in more detail below, a RAID subsystem includes multiple disk drives. One drive can fail and information stored on the other drives can be used to regenerate the information that was stored on the failed drive. Accordingly, by placing the transformation operator information on a RAID drive, the transformation operator can be recreated even if the drive containing the transformation operator fails. Moreover, the fault tolerance of a RAID storage system is thereby merged with the file recovery technique described above.

Referring now to FIG. 4, computer system 100, constructed in accordance with a preferred embodiment of the invention, preferably comprises one or more central processing units (“CPUs”) 10, main memory 12, host bridge 14, expansion bus 18, input/output controller hub 22, a firmware hub 26, a super I/O controller 28, one or more disk array controllers 50 and a plurality of disk drives 52. Computer system 100 preferably is a server system, although that is not necessarily the case. The computer system 100 may comprise multiple CPUs, such as CPUs 10A, 10B, 10C, 10D, arranged to permit simultaneous, multi-tasking to occur. The CPUs may comprise, for example, Pentium® III processors from Intel Corp., or other suitable processors. It should be understood that the system 100 can include any number of CPUs.

Briefly, the CPU array 10 couples to a main memory array 12 and a variety of other peripheral computer system components through an integrated host bridge logic device 14. The main memory array 12 preferably couples to the host bridge logic 14 through a memory bus 16, and the host bridge logic 14 preferably includes a memory control unit (not shown) that controls transactions to the main memory 12 by asserting the necessary control signals during memory accesses. The main memory 12 functions as the working memory for the CPUs 10 and generally includes a conventional memory device or array of memory devices in which program instructions and data are stored. The main memory array 12 may comprise any suitable type of memory such as Dynamic Random Access Memory (“DRAM”) or any of the various types of DRAM devices. In the preferred embodiment shown in FIG. 4, the primary expansion bus 18 comprises a Hub-link bus which is a proprietary bus of the Intel Corporation. However, computer system 100 is not limited to any particular type of primary expansion bus, and thus other suitable buses may be used. Moreover, the architecture shown in FIG. 4 is only exemplary of one suitable architecture, and any suitable architecture can be used.

In addition to the host bridge device 14, the computer system 100 also includes another bridge logic device 22 that bridges the primary expansion bus 18 to various secondary buses including a low pin count (“LPC”) bus 24 and a peripheral component interconnect (“PCI”) bus 20 (referred to as the “host” PCI bus). In accordance with the preferred embodiment, the bridge device 22 generally controls the flow of data to and from the device to which it connects. Although the hub 22 of FIG. 4 is shown only to support the LPC bus 24 and the PCI bus 20, various other secondary buses may be supported by the hub 22 instead of, or in addition to, LPC bus 24 and PCI bus 20.

Referring still to FIG. 4, the firmware hub 26 couples to the hub 22 by way of the LPC bus 24. The firmware hub 26 preferably comprises a ROM device which contains code that is executable by the CPU array 10. This executable code preferably includes Basic Input/Output System (“BIOS”) code that permits the computer to conduct the Power On Self Test (“POST”) as well as to communicate with various I/O devices during normal system operations, as would be known by those of ordinary skill in the art.

The super input/output controller 28 also couples to the hub 22 via LPC bus 24 and controls various system functions including interfacing with various input and output devices such as keyboard 30. The super I/O controller 28 may further interface, for example, with a system pointing device such as a mouse 32, various serial ports (not shown) and floppy drives (not shown).

The computer system 100 of FIG. 4 also includes one or more disk array controllers such as the three disk array controllers 50A, 50B, 50C coupled to the hub 22 by way of the host PCI bus 20. Each disk array controller 50 preferably is implemented as a separate expansion card, but can also be implemented on the server's main system board which also contains the CPU array 10, main memory 12, host bridge 14, ICH 22, firmware hub 24, and super I/O controller 28. Further, each disk array controller 50 couples to a plurality of hard drives 52A, 52B, 52C. Such a disk drive configuration is typical of the well-known RAID storage system. A RAID storage system typically include multiple data drives on which data is stored and a “parity” drive in which parity data is stored. The parity data permits the contents of any one data drive to be calculated in the event one of the drives becomes non-operational. A RAID system thus is “fault tolerant” meaning that it can recover from a loss of one of its disk drives. RAID storage systems are generally known to those of ordinary skill in the art. It should be understood that while FIG. 4 shows three array controllers 50 and five hard drives in each RAID set 52, computer system 100 may support any number of such controllers and hard drives.

In accordance with the preferred embodiment of FIG. 4, the transformation operators, such as 72, 82, 86, 90 and 92, are stored on one or more of the hard drives comprising the RAID system. An example of this is transformation operator 54. By including the transformation operator on a RAID drive, the means by which an older version of a file can be retrieved is itself fault tolerant, thereby alleviating one or more of the problems discussed previously. For example, a separate set of backup equipment is not needed. Further still, the system can still retrieve the backup related information (i.e., the transformation operators) even if the storage medium on which they are stored fails. Overall, the backup capabilities of the system of FIG. 4 is simple, requires much less storage capacity than storing old copies of entire files, does not require additional equipment and is fault tolerant.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A method of backing up a file, comprising:
(a) making a change to an original version of a file thereby creating a new version of the file;
(b) saving said new version;
(c) computing a transformation operator which is indicative of the differences between the original version of the file and the new version; and
(d) saving said transformation operator.

2. The method of claim 1 wherein (d) includes saving said transformation operator in a separate file.

3. The method of claim 2 wherein said separate file containing said transformation operator is stored on a storage medium that also contains said new file version.

4. The method of claim 3 wherein said storage medium comprises a RAID storage subsystem.

5. The method of claim 1 wherein said transformation operator includes a difference value, said difference value being the difference between a numerical value in the original file version and a numerical value in the new file version.

6. The method of claim 1 wherein said transformation operator includes words or binary encoded values that have been deleted from the original file version to produce the new file version.

7. The method of claim 6 wherein said transformation operator also includes words or binary encoded values that are present in the new file version but are not present in the original file version.

8. The method of claim 1 further including making a further change to said new file version to create a second new file version, saving said second new file version, computing a second transformation operator which is indicative of the differences between the new file version and the second new file version, and saving said second transformation operator.

9. The method of claim 1 further including making a further change to said new file version to create a second new file version, saving said second new file version, computing a second transformation operator which is indicative of the differences between the original file version and the second new file version, and saving said second transformation operator.

10. A method of recovering an original version of a file that has been overwritten by a new version of the file, comprising:
(a) retrieving a transformation operator which is indicative of the differences between the original version of the file and the new file version; and
(b) applying said transformation operator to the new file version.

11. The method of claim 10 wherein said transformation operator is stored in a separate file.

12. The method of claim 11 wherein said separate file containing said transformation operator is stored on a storage medium that also contains said new file version.

13. The method of claim 12 wherein said storage medium comprises a RAID storage subsystem.

14. The method of claim 10 wherein said transformation operator includes a difference value, said difference value being the difference between a numerical value in the original file version and a numerical value in the new file version.

15. The method of claim 10 wherein said transformation operator includes words or binary encoded values that have been deleted from the original file version to produce the new file version.

16. The method of claim 15 wherein said transformation operator also includes words or binary encoded values that are present in the new file version but are not present in the original file version.

17. A computer system, comprising:
a processor;
an input device coupled to said processor; and
a non-volatile a storage device coupled to said processor, said storage device containing files and containing a transformation operator which is indicative of the differences between a first version of a file and a second version of the file.

18. The computer system of claim 17 wherein said transformation operator is stored in a file that is separate from the file containing the second version.

19. The computer system of claim 17 wherein said storage device comprises a RAID storage subsystem.

20. The computer system of claim 17 wherein said transformation operator includes a difference value, said difference value being the difference between a numerical value in the first file version and a numerical value in the second file version.

21. The computer system of claim 17 wherein said transformation operator includes words or binary encoded values that have been deleted from the first file version to produce the second file version.

22. The computer system of claim 21 wherein said transformation operator also includes words or binary encoded values that are present in the first file version but are not present in the second file version.

23. The computer system of claim 17 wherein said second file version has been changed further into a third file version, and said storage device also contains a second transformation operator which is indicative of the differences between the second file version and the third file version.

24. The computer system of claim 17 wherein said second file version has been changed further into a third file version, and said storage device also contains a second transformation operator which is indicative of the differences between the first file version and the third file version.

25. A computer system, comprising:
a processor; and
a non-volatile a storage device coupled to said processor, said storage device containing files, one of said files being a third version and having two prior sequential versions, the earliest version being a first version and a latter version being a second version, and said storage device contains a first transformation operator which is indicative of the differences between the first version and the third version and said storage device contains a second transformation operator which is indicative of the differences between the second version and the third version.

26. The computer system of claim 25 wherein said storage device comprises a RAID storage subsystem.

27. The computer system of claim 25 wherein said transformation operators include a difference value, said difference value being the difference between a numerical value in one file version and a numerical value in another file version.

28. The computer system of claim 25 wherein said transformation operators include words or binary encoded values that have been deleted from one file version to produce another file version.

29. The computer system of claim 28 wherein said transformation operators also include words or binary encoded values that are present in one file version but are not present in another file version.
